(19) United States
(12) Patent Application Publication
(10) Pub. No.: US 2012/0064247 A1
(43) Pub. Date: Mar. 15, 2012

(54) METHOD FOR FORMING CU FILM, AND STORAGE MEDIUM

(75) Inventors: Kenji Hiwa, Nirasaki-shi (JP); Yasuhiko Kojima, Nirasaki-shi (JP)

(73) Assignee: TOKYO ELECTRON LIMITED, Tokyo (JP)

(21) Appl. No.: 13/229,142

(22) Filed: Sep. 9, 2011

Related U.S. Application Data
(63) Continuation of application No. PCT/JP10/51592, filed on Feb. 4, 2010.

(30) Foreign Application Priority Data
Mar. 10, 2009 (JP) 2009-056825

(51) Int. Cl. C23C 16/06; B05C 11/00

(52) U.S. Cl. 427/250; 118/697

(57) ABSTRACT

A film-forming source material composed of a Cu complex is supplied to a wafer, which is kept at a relatively high first temperature and has a Ru film as a film-forming base film, and initial nuclei of Cu are formed on the wafer. Then, the film-forming source material composed of the Cu complex is supplied to the wafer kept at a relatively low second temperature, and Cu is deposited on the wafer having the initial nuclei of Cu formed thereon.

This application is a Continuation Application of PCT International Application No. PCT/JP2010/051592 filed on Feb. 4, 2010, which designated the United States.

### FIELD OF THE INVENTION

The present invention relates to a method for forming a Cu film by chemical vapor deposition (CVD) on a substrate such as a semiconductor substrate or the like, and a storage medium.

### BACKGROUND OF THE INVENTION

Recently, along with the trend toward high speed of semiconductor devices and miniaturization of wiring patterns, Cu having higher conductivity and electromigration resistance than Al attracts attention as a material for wiring, a Cu plating seed layer, and a contact plug.

As for a method for forming a Cu film, physical deposition vapor (PVD) has been widely used. However, it is disadvantageous in that a step coverage becomes poor due to miniaturization of semiconductor devices.

Therefore, as for a method for forming a Cu film, there is used CVD for forming a Cu film on a substrate by a thermal decomposition reaction of a source gas containing Cu or by a reduction reaction of the source gas by a reducing gas. A Cu film formed by CVD (CVD-Cu film) has a high step coverage and a good film formation property for a thin, long and deep pattern. Thus, the Cu film has high conformability to a fine pattern and is suitable for formation of wiring, a Cu plating seed layer and a contact plug.

In the case of using a method for forming a Cu film by CVD, there is suggested a technique for using as a film-forming source material (precursor) a Cu complex such as copper hexafluoroacetylacetonate trimethylvinylsilane (Cu(hfac)TMVS) or the like and thermally decomposing the Cu complex (see, e.g., Japanese Patent Application Publication No. 2000-282242).

When a CVD-Cu film is formed by using a Cu complex as a source material, an initial nucleus is formed on a surface of a base film and, then, Cu is deposited thereon, which results in a Cu film. In order to form a Cu film having good surface properties, it is required to increase an initial nucleus density and perform film formation while preventing agglomeration.

A monovalent Cu complex is widely used as a film-forming source material, so that a Cu film can be formed without agglomeration at a temperature of about 130 to 150° C. However, a long period of time is required to form an initial nucleus, and a film forming speed is decreased.

### SUMMARY OF THE INVENTION

In view of the above, the present invention provides a method for forming a Cu film which is capable of forming a CVD-Cu film having good surface properties at a high film forming speed.

The present invention also provides a storage medium for storing a program for performing the film forming method.

In accordance with an aspect of the present invention, there is provided a method for forming a Cu film on a substrate by a CVD method, including: forming initial nuclei of Cu on a substrate by supplying a film-forming source material including a Cu complex to the substrate kept at a relatively high first temperature; and depositing Cu on the substrate having the initial nuclei of Cu formed thereon by supplying a film-forming source material including a Cu complex to the substrate kept at a relatively low second temperature.

In accordance with another aspect of the present invention, there is provided computer readable storage medium storing a program for controlling a film forming apparatus, wherein the program, when executed, controls the film forming apparatus in a computer such that a method for forming a Cu film is performed, the method for forming a Cu film including: forming initial nuclei of Cu on a substrate by supplying a film-forming source material including a Cu complex to the substrate kept at a relatively high first temperature; and depositing Cu on the substrate having the initial nuclei of Cu formed thereon by supplying a film-forming source material including a Cu complex to the substrate kept at a relatively low second temperature.

### BRIEF DESCRIPTION OF THE DRAWINGS

FIG. 1 is a substantial cross sectional view showing an exemplary configuration of a film forming apparatus for performing a film forming method in accordance with a first embodiment of the present invention.

FIG. 2 is a flowchart showing the method in accordance with the first embodiment of the present invention.

FIG. 3 is a schematic diagram showing a state in which initial nuclei of Cu are formed on a CVD-Ru film as a base film.

FIG. 4 is a schematic diagram showing a state in which Cu is deposited to cover the initial nuclei of Cu and a Cu film is formed.

FIG. 5 is a schematic diagram showing an exemplary configuration of a film forming apparatus for performing a film forming method in accordance with a second embodiment of the present invention.

FIG. 6 is a flowchart showing the film forming method in accordance with the second embodiment of the present invention.

FIG. 7 is a schematic diagram showing an exemplary configuration of a film forming apparatus for performing a film forming method in accordance with a third embodiment of the present invention.

FIG. 8 is a substantial cross sectional view showing a preliminary heating unit of the apparatus of FIG. 7.

FIG. 9 is a substantial cross sectional view showing a Cu film formation unit of the apparatus of FIG. 7.

FIG. 10 is a flowchart showing the film forming method in accordance with the third embodiment of the present invention.

FIG. 11 is a schematic diagram showing an exemplary configuration of a film forming apparatus for performing a film forming method in accordance with a fourth embodiment of the present invention.

FIG. 12 is a flowchart showing the film forming method in accordance with the fourth embodiment of the present invention.

FIG. 13A is a scanning electron microscope image showing a state obtained after the initial nuclei are formed by applying the third embodiment of the present invention.

FIG. 13B is a scanning electron microscope image showing a state obtained after Cu is deposited by applying the third embodiment of the present invention.

### DETAILED DESCRIPTION OF THE EMBODIMENTS

Hereinafter, embodiments of the present invention will be described with reference to the accompanying drawings which form a part hereof.

### First Embodiment

(Configuration of a Film Forming Apparatus for Performing a Film Forming Method in Accordance with a First Embodiment of the Present Invention)

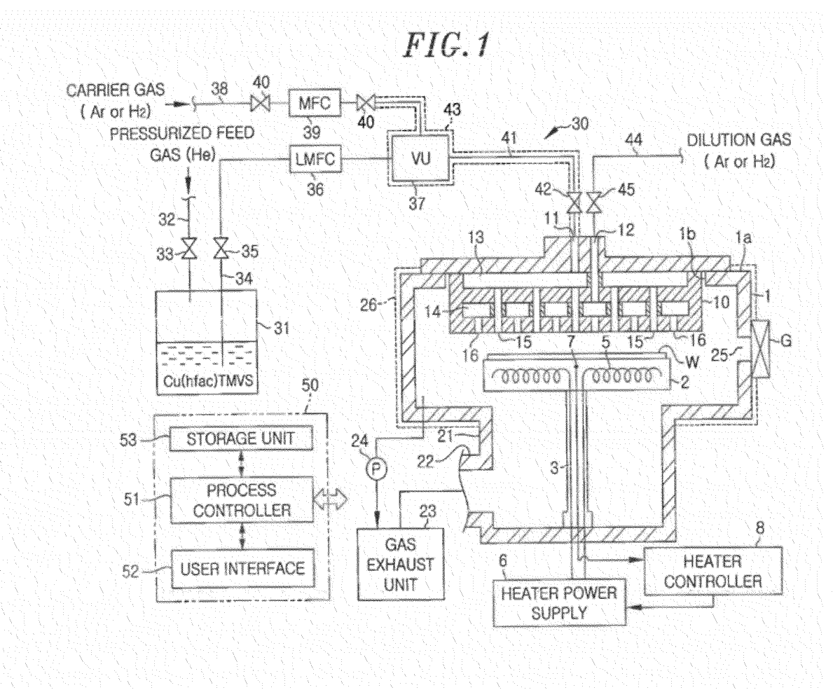

FIG. 1 is a substantial cross sectional view showing an exemplary configuration of a film forming apparatus for performing a film forming method in accordance with a first embodiment of the present invention.

A film forming apparatus 100 includes a substantially cylindrical airtight chamber 1 as a processing chamber, and a susceptor 2 provided in the chamber 1. The susceptor 2 for horizontally supporting a semiconductor wafer W as a substrate to be processed is supported by a cylindrical supporting member 3 provided at the center of the bottom portion of the chamber 1. The susceptor 2 is made of ceramic such as AlN or the like.

Further, a heater 5 is buried in the susceptor 2, and a heater power supply 6 is connected to the heater 5. Meanwhile, a thermocouple 7 is provided near the top surface of the susceptor 2, and a signal from the thermocouple 7 is transmitted to a heater controller 8. The heater controller is configured to transmit an instruction to the heater power supply 6 in accordance with the signal from the thermocouple 7 and control the wafer W to a predetermined temperature by controlling the heating of the heater 5.

A circular opening 1b is formed at a ceiling wall 1a of the chamber 1, and a shower head 10 is fitted in the circular opening 1b to protrude in the chamber 1. The shower head 10 injects a film forming gas supplied from a gas supply mechanism 30 to be described later into the chamber 1. The shower head 10 has, at an upper portion thereof, a first inlet line 11 for introducing a Cu complex having a vapor pressure higher than that of a by-product produced by thermal decomposition of a film forming gas, e.g., copper hexafluoroacetylacetonate trimethylvinylsilane (Cu(hfac)TMVS) as a monovalent β-diketone complex, and a second inlet line 12 for introducing a dilution gas into the chamber 1. As for the dilution gas, Ar gas or H₂ gas is used, for example.

The inner space of the shower head 10 is separated into an upper space 13 and a lower space 14. The first inlet line 11 is connected to the upper space 13, and a first gas injection path 15 extends from the upper space 13 to the bottom surface of the shower head 10. The second inlet line 12 is connected to the lower space 14, and a second gas injection path 16 extends from the lower space 14 to the bottom surface of the shower head 10. In other words, the shower head 10 is configured to separately inject a Cu complex gas as a film-forming source material and a dilution gas from the gas injection paths 15 and 16.

A gas exhaust chamber 21 is provided at a bottom wall of the chamber 1 so as to protrude downward. A gas exhaust line 22 is connected to a side wall of a gas exhaust chamber 21, and a gas exhaust unit 23 including a vacuum pump, a pressure control valve or the like is connected to the gas exhaust line 22. By driving the gas exhaust unit 23, the inside of the chamber 1 can be set to a predetermined depressurized state.

Further, a pressure in the chamber 1 is detected by a pressure gauge 24. The pressure in the chamber 1 are controlled by adjusting an opening degree of the pressure control valve of the gas exhaust unit 23 based on the detected value. In the present embodiment, the pressure is controlled to a level at which the desorption and diffusion of the by-product adsorbed on the surface of the wafer W proceeds.

Formed on the sidewall of the chamber 1 are a loading/unloading port 25 for loading and unloading the wafer W with respect to a wafer transfer chamber (not shown) and a gate valve G for opening and closing the loading/unloading port 25. Moreover, a heater 26 is provided on a wall of the chamber 1, and can control the temperature of the inner wall of the chamber 1 during the film formation.

The gas supply mechanism 30 has a film-forming source material tank 31 for storing, as a film-forming source material, a monovalent Cu complex, e.g., Cu(hfac)TMVS that is a monovalent β-diketone complex in a liquid state. As for the Cu complex of a film-forming source material, it is possible to use another monovalent β-diketone complex such as Cu(hfac)ATMS, Cu(hfac)DMDVS, Cu(hfac)TMOVS or the like. In the case of using a monovalent Cu complex in a solid state at a room temperature, it can be stored in the film-forming source material tank 31 while being dissolved in a solvent.

A pressurized feed gas line 32 for supplying a pressurized feed gas such as He gas or the like is inserted from above into the film forming material tank 31, and a valve 33 is installed in the pressurized feed gas line 32. Further, a source material discharge line 34 is inserted from above into the film-forming source material tank 31, and a vaporizer (VU) 37 is connected to the other end of the source material discharge line 34. A valve 35 and a liquid mass flow controller 36 are installed in the source material discharge line 34.

By introducing a pressurized feed gas into the film-forming source material tank 31 via the pressurized feed gas line 32, a Cu complex, e.g., Cu(hfac)TMVS, in the film-forming source material tank 31 is supplied in a liquid state to the vaporizer 37. At this time, the liquid supply amount is controlled by the liquid mass flow controller 36.

A carrier gas line 38 for supplying Ar or H₂ gas as a carrier gas is connected to the vaporizer 37. A mass flow controller 39 and two valves 40 positioned at both sides of the mass flow controller 39 are provided in the carrier gas line 38.

Moreover, a film-forming source material gas supply line 41 for supplying a Cu complex in a vapor state toward the shower head 10 is connected to the vaporizer 37. A valve 42 is installed in the film-forming source material gas supply line 41, and the other end of the film-forming source material gas supply line 41 is connected to the first inlet line 11 of the shower head 10. Furthermore, the Cu complex vaporized by the vaporizer 37 is discharged to the film-forming source material gas supply line 41 while being carried by the carrier gas, and then is supplied into the shower head 10 from the first inlet line 11.

A heater 43 for preventing condensation of the film-forming source material gas is provided at a region including the vaporizer 37, the film-forming source material gas supply line 41, and the valve 40 disposed at the downstream side of the carrier gas line. The heater 43 is powered by a heater power supply (not shown), and the temperature of the heater 43 is controlled by a controller (not shown).

A dilution gas supply line 44 for supplying a dilution gas is connected to the second inlet line 12 of the shower head 10. A valve 45 is installed in the dilution gas line 44. Further, Ar gas or H₂ gas is supplied as a dilution gas from the second inlet line 12 into the shower head 10 through the dilution gas supply line 44.

The film forming apparatus 100 includes a control unit 50 which is configured to control the respective components, e.g., the heater power supply 6, the gas exhaust unit 23 (pressure control valve, vacuum pump), the mass flow controllers 36 and 39, the valves 33, 35, 40, 42 and 45 and the like, and control the temperature of the susceptor 2 by using the heater controller 8. The control unit 50 includes a process controller 51 having a micro processor (computer), a user interface 52 and a storage unit 53. The respective components of the film forming apparatus 100 are electrically connected to and controlled by the process controller 51.

The user interface 52 is connected to the process controller 51, and includes a keyboard through which an operator performs a command input to manage the respective units of the film forming apparatus 100, a display for visually displaying the operational states of the respective components of the film forming apparatus 100, and the like.

The storage unit 53 is also connected to the process controller 51, and stores therein control programs to be used in realizing various processes performed by the film forming apparatus 100 under the control of the process controller 51, control programs, i.e., processing recipes, to be used in operating the respective components of the film forming apparatus 100 to carry out predetermined processes under processing conditions, various database and the like. The processing recipes are stored in a storage medium provided in the storage unit 53. The storage medium may be a fixed medium such as a hard disk or the like, or a portable device such as a CD-ROM, a DVD, a flash memory or the like. Alternatively, the recipes may be suitably transmitted from other devices via, e.g., a dedicated transmission line.

If necessary, a predetermined processing recipe is read out from the storage unit 53 by the instruction via the user interface 52 and is executed by the process controller 51. Accordingly, a desired process is performed in the film forming apparatus 100 under the control of the process controller 51.

(Method for Forming a Cu Film in Accordance with the First Embodiment of the Present Invention)

Hereinafter, a method for forming a Cu film in accordance with the present embodiment which uses the film forming apparatus configured as described above will be described.

Here, an example in which a Cu film is formed on a wafer W having thereon a Ru film (CVD-Ru film) formed by CVD while using as a film-forming source material Cu(hfac)TMVS that is a monovalent β-diketone complex will be described. Preferably, the CVD-Ru film is formed by using Ru₃(CO)₁₂ as a film-forming source material. Accordingly, a CVD-Ru film of high purity can be obtained, and a pure and robust interface of Cu and Ru can be formed. As for an apparatus for forming a CVD-Ru film, there can be used one having a configuration same as that of the apparatus shown in FIG. 1 except that vapor generated by heating Ru₃(CO)₁₂ in a solid state at a room temperature is supplied.

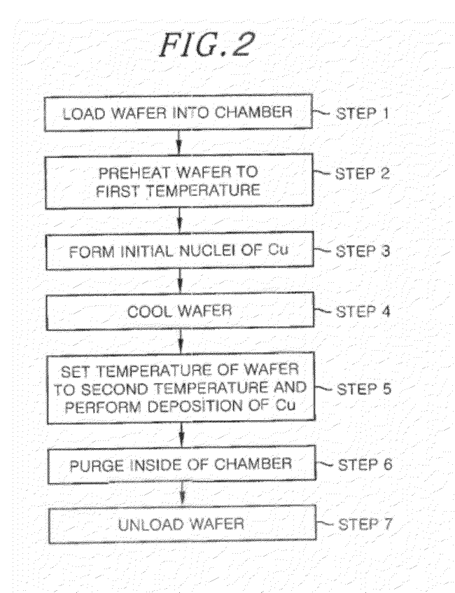

FIG. 2 is a flowchart showing the method for forming a Cu film in accordance with the first embodiment of the present invention.

First of all, the susceptor 2 is heated to, e.g., about 220 to 250° C. by the heater 5. Next, the gate valve G opens, and the wafer W having the above structure is loaded into the chamber 1 by a transfer device (not shown) and then is mounted on the susceptor 2 (step 1).

Then, the inside of the chamber 1 is exhausted by the gas exhaust unit 23 such that a pressure in the chamber 1 is set to a relatively high first pressure, e.g., about 133 to 1333 Pa (about 1 to 10 Torr), and the wafer W is pre-heated to a relatively high first temperature substantially the same as the temperature of the susceptor 2 (step 2). At the same time, a carrier gas is supplied into the chamber 1 at a flow rate of about 100 to 1500 mL/min(sccm) via the carrier gas supply line 38, the vaporizer 37, the film-forming source material gas line 41, and the shower head 10, and a dilution gas is supplied into the chamber 1 at a flow rate of about 0 to 1500 mL/min(sccm) via the dilution gas supply line 44 and the shower head 10. In this way, the stabilization is carried out.

After a predetermined period of time has elapsed, the pressure in the chamber 1 is decreased to a relatively low second pressure, e.g., about 4.0 to 13.3 Pa (about 0.03 to 0.1 Torr). At the same time, liquid Cu(hfac)TMVS is vaporized by the vaporizer 37 at about 50 to 70° C. and introduced into the chamber 1 in a state where the carrier gas and the dilution gas are supplied. Hence, an initial nucleus of Cu is formed (step 3). At this time, the Cu(hfac)TMVS is supplied at a flow rate of, e.g., about 50 to 1000 mg/min.

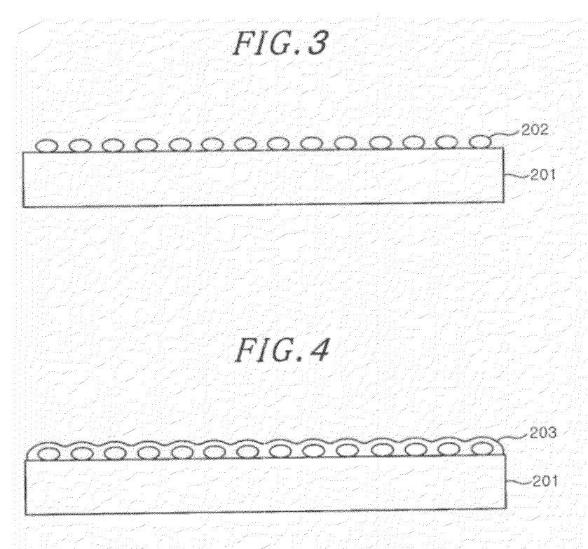

Cu(hfac)TMVS as a film-forming source material is decomposed on the wafer W heated by the heater 5 of the susceptor 2 by the reaction described in the following Eq. (1). Accordingly, initial nuclei of Cu 202 is formed on the CVD-Ru film 201 as a base film, as can be seen from FIG. 3.

2Cu(hfac)TMVS→Cu+Cu(hfac)₂+2TMVS Eq. (1)

The initial temperature of the wafer W in this process is substantially the same as the temperature of the susceptor 2, e.g., about 220 to 250° C. Since it is higher than a general film forming temperature, the formation of initial nuclei is facilitated and high-density initial nuclei are formed within a short period of time.

At this time, since the pressure in the chamber 1 is set to the relatively low second pressure, the heat transfer from the susceptor 2 to the wafer W is reduced, and the temperature of the wafer W is gradually lowered. However, the temperature of the wafer W is maintained at a sufficiently high level during the initial nucleus formation.

At the time when the initial nucleus formation is completed, the temperature of the wafer W is higher than the film formation temperature. Thus, the supply of Cu(hfac)TMVS is stopped, and the wafer W is cooled while maintaining the pressure in the chamber 1 at the second pressure (step 4).

At the time when the wafer W is cooled to the relatively low second temperature as a film forming temperature, e.g., about 130 to 150° C., the supply of Cu(hfac)TMVS is restarted to deposit Cu (step 5). At this time, Cu(hfac)TMVS is supplied at a flow rate of, e.g., about 50 to 1000 mg/min. As a consequence, as shown in FIG. 4, Cu is deposited to cover the initial nuclei of Cu 202 by the reaction of Eq. (1), and a Cu film 203 is formed.

At this time, the film formation is carried out at the relatively low second temperature, e.g., about 130 to 150° C. Therefore, Cu is hardly agglomerated, and a Cu film having high smoothness and good surface property is formed.

After the formation of the Cu film is completed, the inside of the chamber 1 is purged (step 6). At this time, the inside of the chamber 1 is purged by supplying, as a purge gas, a carrier gas and a dilution gas while stopping the supply of Cu(hfac)TMVS and setting the vacuum pump of the gas exhaust unit 23 to a pull-end state. In this case, it is preferable to intermittently supply the carrier gas in order to rapidly purge the inside of the chamber 1.

After completion of the purge process, the gate valve G is opened, and the wafer W is unloaded through the loading/unloading port 25 by a transfer device (not shown) (step 7). In this manner, a series of processes for a single wafer W is completed.

As described above, in the present embodiment, nuclei of Cu are formed at the relatively high first temperature (higher than the second temperature as a film forming temperature), so that it is possible to shorten a period of time required to form the nuclei of Cu, especially an incubation time. Thereafter, Cu is deposited at the relatively low second temperature (lower than the first temperature), so that a Cu film having high smoothness and good surface property can be formed while suppressing agglomeration of Cu. In other words, a CVD-Cu film having good surface properties can be formed at a high film forming speed.

Moreover, in the present embodiment, the formation of the initial nuclei and the deposition of Cu are carried out in a single chamber while varying a pressure in the chamber. Accordingly, the transfer time is not required, and the film forming speed can be extremely increased.

### Second Embodiment

(Configuration of a Film Forming Apparatus for Performing a Film Forming Method in Accordance with a Second Embodiment of the Present Invention)

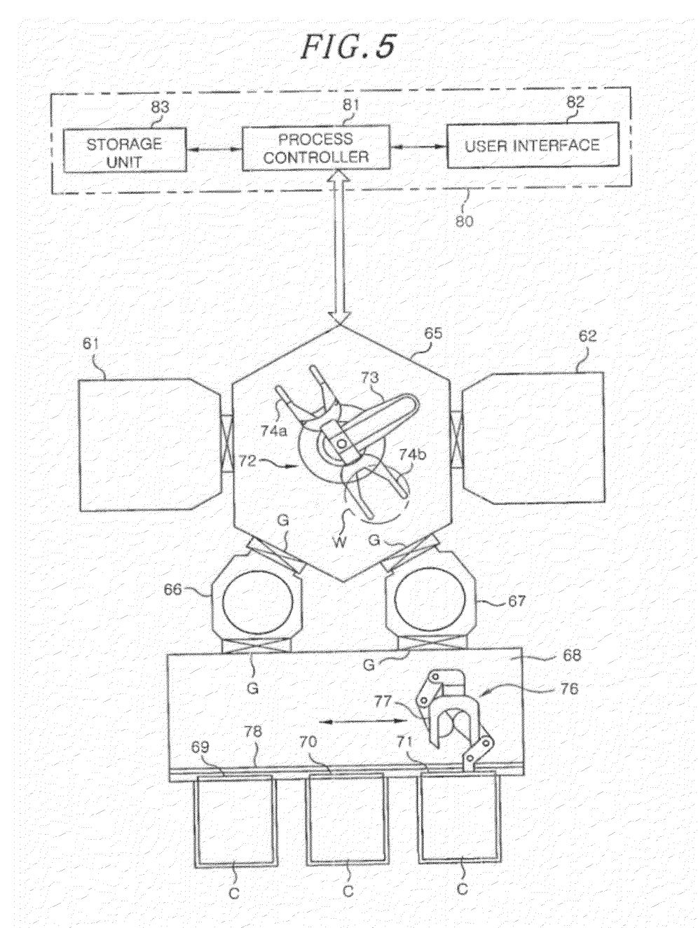

FIG. 5 is a schematic diagram showing an example of a film forming apparatus for performing a film forming method in accordance with a second embodiment of the present invention. This film forming apparatus is of a multi-chamber type capable of consecutively performing in-situ the formation of initial nuclei of Cu and the deposition of Cu while maintaining a vacuum state.

This film forming apparatus includes a Cu initial nucleus formation unit 61 and a Cu deposition unit 62 which are maintained in a vacuum state and connected to a transfer chamber 65 via gate valves G. Further, load-lock chambers 66 and 67 are connected to the transfer chamber 65 via gate valves G. The transfer chamber 65 is maintained in a vacuum state. A loading/unloading chamber 68 in an atmospheric atmosphere is provided at the side of the load-lock chambers 66 and 67 which is opposite to the transfer chamber 65 is provided. Moreover, three carrier attachment ports 69, 70 and 71 to which carriers C capable of accommodating wafers W are attached are provided at the side of the loading/unloading chamber 68 which is opposite to the load-lock chambers 66 and 67.

Provided in the transfer chamber 65 is a transfer device 72 for loading/unloading a wafer W with respect to the Cu initial nucleus formation unit 61, the Cu deposition unit 62, and the load-lock chambers 66 and 67. The transfer device 72 is disposed at a substantially central portion of the transfer chamber 65, and has at a leading end of a rotatable and extensible/contractible portion 73 two support arms 74a and 74b for supporting wafers W. The two support arms 74a and 74b are attached to the rotatable and extensible/contractible portion 73 so as to face the opposite directions.

Installed in the loading/unloading chamber 68 is a transfer device 76 for loading/unloading wafers W with respect to the carriers C and the load-lock chambers 66 and 67. The transfer device 76 has a multi-joint arm structure, and can move on a rail 78 along the arrangement direction of the carriers C. The transfer device 76 transfers wafers W mounted on a support arm 77 provided at the leading end thereof.

This film forming apparatus includes a control unit 80 for controlling each component thereof. The control unit 80 controls each component of the Cu initial nucleus formation unit 61, each component of the Cu deposition unit 62, the transfer devices 72 and 76, a gas exhaust system (not shown) of the transfer chamber 65, opening and closing of the gate valves G and the like. The control unit 80 has a process controller 81 having a micro processor (computer), a user interface 82, and a storage unit 83 of which configurations are the same as those of the process controller 51, the user interface 52 and the storage unit 53 shown in FIG. 1.

In addition, the Cu initial nucleus formation unit 61 and the Cu deposition unit 62 have the configurations same as that of the film forming apparatus 100 of the first embodiment.

(Method for Forming a Cu Film in Accordance with the Second Embodiment of the Present Invention)

Hereinafter, a method for forming a Cu film of the present embodiment which uses the film forming apparatus configured as described above will be described.

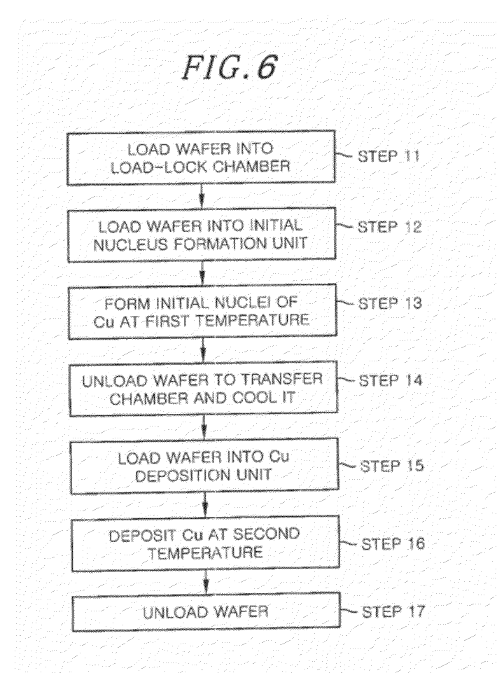

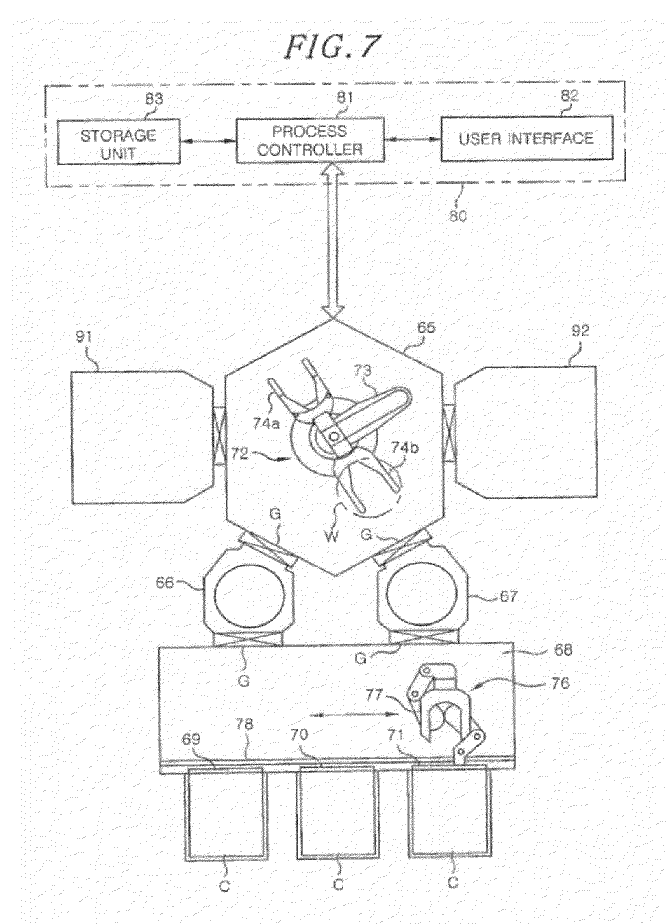

FIG. 6 is a flowchart showing a film forming method in accordance with the second embodiment of the present invention.

First of all, a wafer W is loaded from the carrier C into one of the load-lock chambers 66 and 67 by the transfer device 76 in the loading/unloading chamber 68 (step 11). Next, the load-lock chamber is exhausted to a vacuum state. Thereafter, the wafer W is unloaded by the transfer device 72 in the transfer chamber 65 and then is loaded into the Cu initial nucleus formation unit 61 (step 12).

In the Cu initial nucleus formation unit 61, the wafer W is mounted on the susceptor, and the pressure in the chamber is set to, e.g., about 4.0 to 13.3 Pa (about 0.03 to 0.1 Torr). Further, the temperature of the susceptor is set to a relatively high first temperature, e.g., about 240 to 280° C., and the stabilization is carried out by supplying a carrier gas and a dilution gas as in the first embodiment. Then, in a state where the carrier gas and the dilution gas are supplied, liquid Cu(hfac)TMVS is vaporized by the vaporizer at about 50 to 70° C. and introduced into the chamber, thereby forming initial nuclei of Cu (step 13). Hence, as in the first embodiment, the initial nuclei of Cu 202 is formed on a CVD-Ru film 201 as a base film, as can be seen from FIG. 3. At this time, the liquid Cu(hfac)TMVS is supplied at a flow rate of about 50 to 1000 mg/min.

In this process, the temperature of the susceptor is set to the relatively high first temperature, e.g., about 240 to 280° C., and the temperature of the wafer W is set to a level higher than about 200° C. which is higher than a general film forming temperature of about 150° C. Accordingly, the formation of initial nuclei is facilitated, and high-density initial nuclei can be formed within a short period of time.

Next, the supply of Cu(hfac)TMVS is stopped, and the inside of the chamber is purged. Thereafter, the wafer W is transferred to the transfer chamber 65 by the transfer device 72 and cooled (step 14). At this time, the pressure of the transfer chamber 65 is increased to about 133 to 1333 Pa (about 1 to 10 Torr) in order to facilitate the cooling of the wafer W.

When the wafer W is cooled to the relatively low second temperature as a film forming temperature, e.g., about 130 to 150° C., the wafer W on the transfer device 72 is loaded into the Cu deposition unit 62 (step 15).

In the Cu deposition unit 62, the pressure in the chamber is set to, e.g., about 4.0 to 13.3 Pa (about 0.03 to 0.1 Torr), and the temperature of the susceptor is set to the relatively low second temperature, e.g., about 130 to 150° C. Next, as in the first embodiment, the stabilization is carried out by supplying a carrier gas and a dilution gas into the chamber. Then, in a state where the carrier gas and the dilution gas are supplied, liquid Cu(hfac)TMVS is vaporized by the vaporizer at about 50 to 70° C. and introduced into the chamber, thereby depositing Cu (step 16). At this time, Cu(hfac)TMVS is supplied at a flow rate of about 50 to 1000 mg/min. Hence, as in the first embodiment, Cu is deposited to cover the initial nuclei of Cu 202 by the reaction of Eq. (1), and the Cu film 203 is formed, as can be seen from FIG. 4.

At this time, the film formation is carried out at the relatively low second temperature, e.g., about 130 to 150° C. Therefore, Cu is hardly agglomerated, and a Cu film having high smoothness and good surface properties is formed.

Thereafter, the Cu deposition unit 62 is purged, and the wafer W is unloaded from the Cu deposition unit 62 and transferred to the transfer chamber 65 by the transfer device 72. Next, the wafer W is transferred to one of the carriers C by the transfer device 76 via the load-lock chambers 66 and 67 (step 17).

As described above, in the present embodiment, nuclei of Cu are formed at the relatively high first temperature (higher than the second temperature as a film forming temperature), so that it is possible to shorten a period of time required to form nuclei, especially an incubation time. Thereafter, Cu is deposited at the relatively low second temperature (lower than the first temperature), so that a Cu film having high smoothness and good surface properties can be formed while suppressing agglomeration of Cu. In other words, a CVD-Cu film having good surface properties can be formed at a high film forming speed.

Besides, in the present embodiment, the Cu initial nucleus formation unit 61 and the Cu deposition unit 62 are set under conditions suitable for formation of initial nuclei of Cu and deposition of Cu. Therefore, the waiting time for changing conditions or the like can be shortened even though the wafer transfer time is required.

### Third Embodiment

(Configuration of a Film Forming Apparatus for performing a Film Forming Method in Accordance with a Third Embodiment of the Present Invention)

FIG. 7 is a schematic diagram showing an example of a film forming apparatus for performing a film forming method in accordance with a third embodiment of the present invention. The film forming apparatus of the present embodiment has the configuration same as that of FIG. 5 except that a preliminary heating unit 91 and a Cu film formation unit 92 are provided instead of the Cu initial nucleus formation unit 61 and the Cu deposition unit 62 in the apparatus of the second embodiment. Accordingly, like reference numerals are used to refer to like parts, and the explanation thereof will be omitted.

The preliminary heating unit 91 and the Cu film formation unit 92 are maintained in a vacuum state and connected to the transfer chamber 65 via gate valves G.

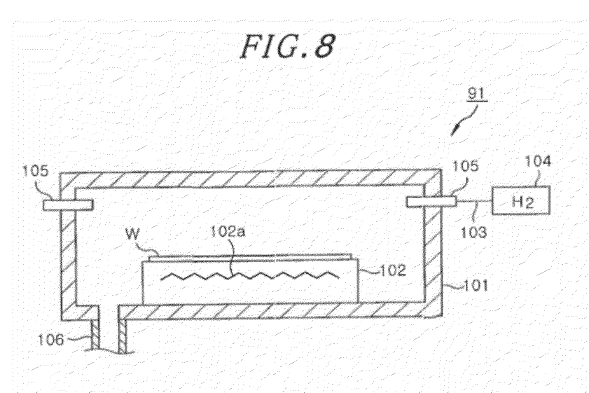

As shown in FIG. 8, the preliminary heating unit 91 includes a chamber 101, a susceptor 102 provided in the chamber 101 and having a heater 102a buried therein, a gas inlet 105 connected via a line 103 to an atmospheric gas supply source 104 for supplying an atmospheric gas, e.g., H₂ gas, and a gas exhaust line 106 connected to a gas exhaust unit (not shown) having a vacuum pump or the like.

In the preliminary heating unit 91, the susceptor 102 is heated by the heater 102a to, e.g., about 350 to 380° C., which is higher than the temperature during the initial nucleus formation, and the chamber 101 is maintained at a high pressure of about 133 to 1333 Pa (about 1 to 10 Torr). As a consequence, the wafer W can be preliminarily heated within a short period of time.

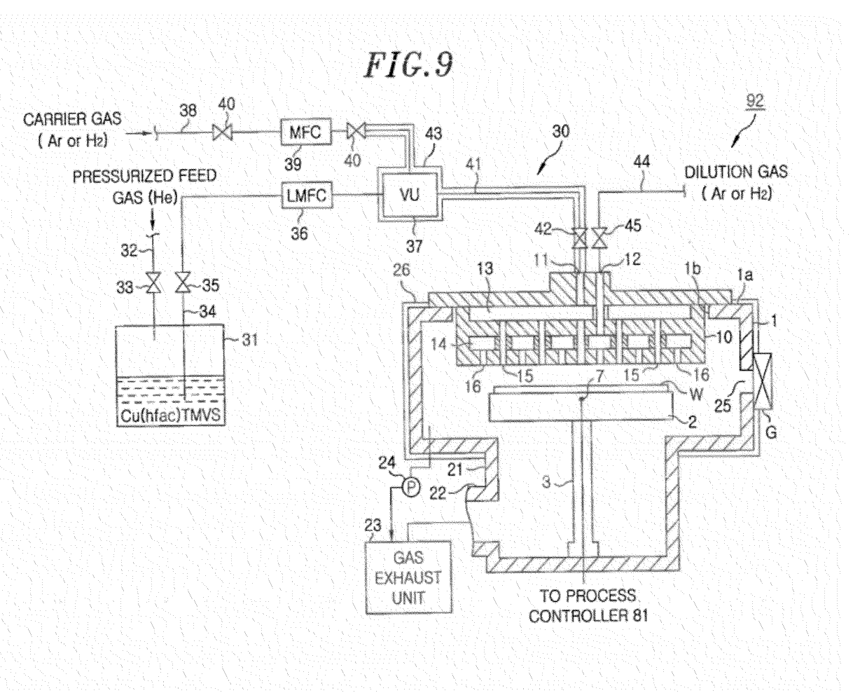

As shown in FIG. 9, the Cu film formation unit 92 has the configuration same as that of the film forming apparatus 100 of FIG. 1 except that the heater 5 is not provided. Since the Cu film formation unit 92 is not provided with the heater, it is possible to prevent Cu from being agglomerated due to heat supplied to the wafer W during the formation of the Cu film. Moreover, the Cu film formation unit 92 of FIG. 9 is the same as the film forming apparatus 100 of FIG. 1 except that the heater 5, the heater power supply 6, the heater controller 8, and the control unit 50 are not provided. Thus, like reference numerals are used to refer to like parts, and the explanation thereof will be omitted. In addition, the signal of the thermocouple 7 is transmitted to the process controller 81 of the control unit 80.

(Method for Forming a Cu Film in Accordance with the Third Embodiment of the Present Invention)

Hereinafter, a method for forming a Cu film of the present embodiment which uses the film forming apparatus configured as described above will be described.

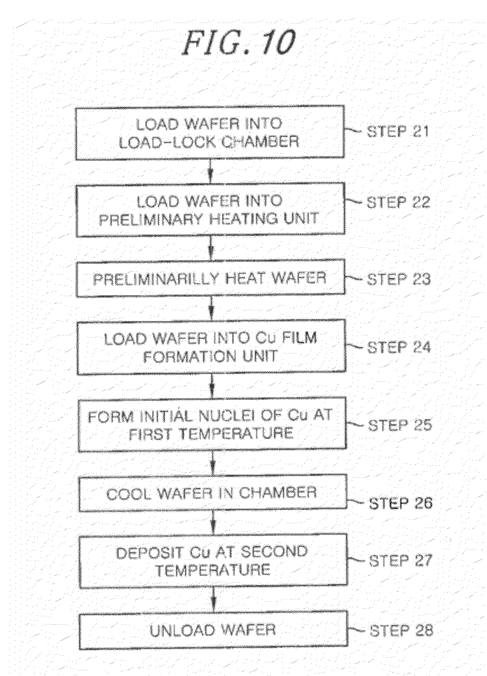

FIG. 10 is a flowchart showing the film forming method in accordance with the third embodiment of the present invention.

First of all, a wafer W is loaded from a carrier C into any one of the load-lock chambers 66 and 67 by the transfer device 76 of the loading/unloading chamber 68 (step 21). Next, the load-lock chamber is exhausted to a vacuum state and, then, the wafer W is unloaded by the transfer device 72 of the transfer chamber 65. Thereafter, the wafer W is loaded into the preliminary heating unit 91 (step 22).

In the preliminary heating unit 91, the wafer W is heated to, e.g., about 320 to 380° C., which is higher than the temperature during the initial nucleus formation, and the chamber 101 is maintained at a high pressure of about 133 to 1333 Pa (about 1 to 10 Torr). In this state, the wafer W is preliminarily heated on the susceptor 102 (step 23). By preliminarily heating the wafer W under the high-temperature and high-pressure conditions, the wafer W can be preliminarily heated to a desired temperature within a short period of time.

Next, the wafer W is unloaded from the preliminary heating unit 92 and loaded into the Cu film formation unit 92 by the transfer unit 72 (step 24).

In the Cu film formation unit 92, the wafer W is mounted on the susceptor 2, and the pressure in the chamber 1 is set to, e.g., about 4.0 to 13.3 Pa (about 0.03 to 0.1 Torr). Then, as in the first embodiment, the stabilization is carried out by supplying a carrier gas and a dilution gas into the chamber 1. When the temperature of the wafer W reaches the relatively high first temperature, e.g., about 240 to 280° C., liquid Cu(hfac)TMVS is vaporized by the vaporizer at about 50 to 70° C. and introduced into the chamber in a state where the carrier gas and the dilution gas are supplied, thereby forming initial nuclei of Cu (step 25). Hence, as in the first embodiment, the initial nuclei of Cu 202 are formed on the CVD-Ru film 201 as a base film, as shown in FIG. 3. At this time, the liquid Cu(hfac)TMVS is supplied at a flow rate of about 50 to 1000 mg/min.

In this process, the initial nuclei of Cu are formed when the temperature of the wafer reaches the relatively high first temperature of about 200° C. or above, e.g., about 240 to 280° C., which is higher than a general film forming temperature of about 150° C. Accordingly, the formation of initial nuclei is facilitated, and a high-density initial nucleus can be formed within a short period of time.

Next, the supply of Cu(hfac)TMVS is stopped, and the wafer W is cooled while maintaining the pressure in the chamber 1 at the above-mentioned level (step 26).

When the wafer W is cooled to the relatively low second temperature as a film forming temperature, e.g., about 130 to 150° C., the supply of Cu(hfac)TMVS is restarted to deposit Cu (step 27). At this time, Cu(hfac)TMVS is supplied at a flow rate of, e.g., about 50 to 1000 mg/min. Accordingly, as in the first embodiment, Cu is deposited to cover the initial nucleus of Cu 202 by the reaction of Eq. (1), and a Cu film 203 is formed, as can be seen from FIG. 4.

At this time, the film formation is carried out at the relatively low second temperature, e.g., about 130 to 150° C. Therefore, Cu is hardly agglomerated, and a Cu film having high smoothness and good surface properties is formed.

Thereafter, the Cu film formation unit 92 is purged, and the wafer W is transferred to the transfer chamber 65 by the transfer device 72. Then, the wafer W is unloaded from the transfer chamber 65 and loaded into any one of the carriers C by the transfer device 76 via the load-lock chambers 66 and 67 (step 28).

As described above, in the present embodiment, a nucleus of Cu is formed at the relatively high first temperature (higher than the second temperature as a film forming temperature), so that it is possible to shorten a period of time required to form a nucleus, especially an incubation time. Thereafter, Cu is deposited at the relatively low second temperature (lower than the first temperature), so that a Cu film having high smoothness and good surface properties can be formed while suppressing agglomeration of Cu. In other words, a CVD-Cu film having good surface properties can be formed at a high film forming speed.

After the wafer W is heated to a temperature higher than the initial nucleus formation temperature by the preliminary heating unit 91, the initial nucleus formation and the Cu deposition are carried out without heating the wafer W in the Cu film formation unit 92 which is separately provided. As a result, residual heat is not transferred to the wafer W, and agglomeration of Cu can be effectively prevented.

### Fourth Embodiment

(Configuration of a Film Forming Apparatus for Performing F Film Forming Method in Accordance with a Fourth Embodiment of the Present Invention)

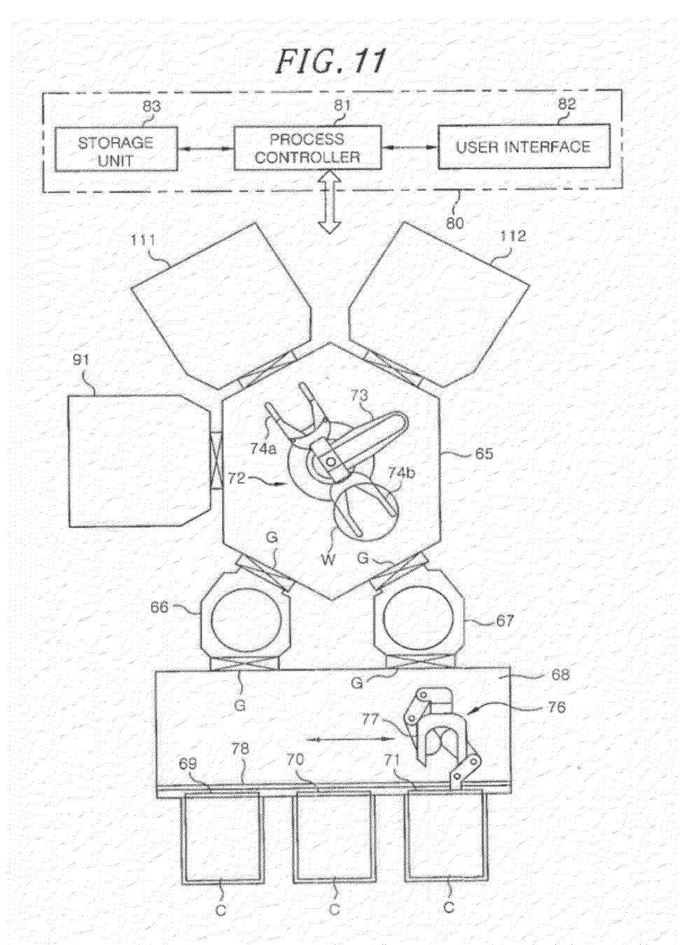

FIG. 11 is a schematic diagram showing an example of a film forming apparatus for performing a film forming method in accordance with a fourth embodiment of the present invention. The film forming apparatus of the present embodiment has the configuration same as that shown in FIG. 7 except that a Cu initial nucleus formation unit 111 and a Cu deposition unit 112 are provided instead of the Cu film formation unit 92 in the apparatus of the third embodiment. Therefore, like reference numerals are used to refer to like parts, and the explanation thereof is omitted.

The Cu initial nucleus formation unit 111 and the Cu deposition unit 112 have the configurations same as that of the Cu film formation unit 92 of the third embodiment.

(Method for Forming a Cu Film in Accordance with the Fourth Embodiment of the Present Invention)

Hereinafter, a method for forming a Cu film of the present embodiment which uses the film forming apparatus configured as described above will be described.

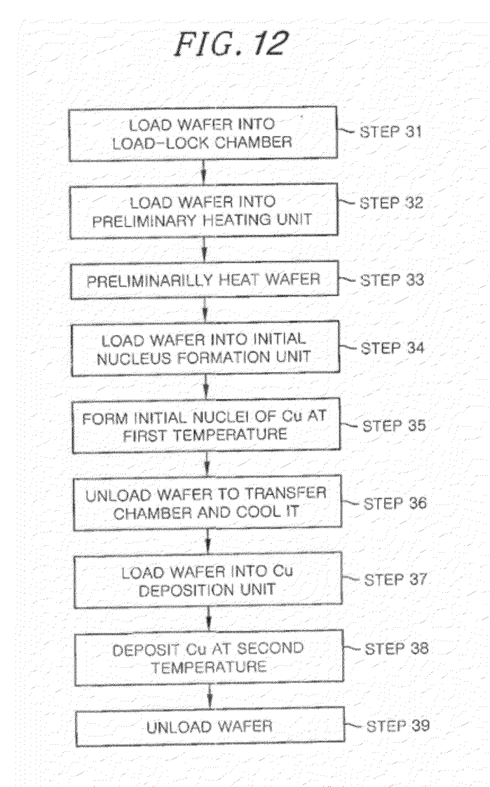

FIG. 12 is a flowchart showing the film forming method in accordance with the fourth embodiment of the present invention.

First of all, a wafer W is loaded from a carrier C into one of the load-lock chambers 66 and 67 by the transfer device 76 of the loading/unloading chamber 68 (step 31). Next, the load-lock chamber is exhausted to a vacuum state and, then, the wafer W is unloaded by the transfer device 72 of the transfer chamber 65. Thereafter, the wafer W is loaded into the preliminary heating unit 91 (step 32).

In the preliminary heating unit 91, as in the third embodiment, the susceptor is heated to, e.g., about 350 to 380° C., which is higher than the temperature during the initial nucleus formation, and the chamber 101 is maintained at a high pressure of about 133 to 1333 Pa (about 1 to 10 Torr). In this state, the wafer W is preliminarily heated on the susceptor 102 (step 33). By preliminarily heating the wafer W under the high-temperature and high-pressure conditions, the wafer W can be preliminarily heated to a desired temperature within a short period of time.

Next, the wafer W is unloaded from the preliminary heating unit 91 by the transfer device 72 and then loaded into the Cu initial nucleus formation unit 111 (step 34).

In the Cu initial nucleus formation unit 111, the wafer W is mounted on the susceptor, and the pressure in the chamber is set to, e.g., about 4.0 to 13.3 Pa (about 0.03 to 0.1 Torr). Further, as in the first embodiment, the stabilization is carried out by supplying a carrier gas and a dilution gas into the chamber 1. When the temperature of the susceptor reaches the relatively high first temperature, e.g., about 240 to 280° C., liquid Cu(hfac)TMVS is vaporized by the vaporizer at about 50 to 70° C. and introduced into the chamber in a state where the carrier gas and the dilution gas are supplied, thereby forming initial nuclei of Cu (step 35). Hence, as in the first embodiment, the initial nuclei of Cu 202 are formed on the CVD-Ru film 201 as a base layer by the reaction of Eq. (1), as can be seen from FIG. 3. At this time, the liquid Cu(hfac)TMVS is supplied at a flow rate of about 50 to 1000 mg/min.

In this process, the initial nuclei are formed when the wafer reaches a temperature higher than about 200° C., e.g., the relatively high first temperature of about 240 to 280° C. which is higher than a general film forming temperature of about 150° C. Since the temperature of the wafer W is higher than about 200° C. which is higher than the general film forming temperature of about 150° C., the formation of initial nuclei is facilitated, and high-density initial nuclei can be formed within a short period of time.

Then, the supply of Cu(hfac)TMVS is stopped, and the inside of the chamber is purged. Next, the wafer W is transferred to the transfer chamber 65 by the transfer device 72 and cooled (step 36). Thereafter, the wafer W is loaded into the Cu deposition unit 112 (step 37).

In the Cu deposition unit 112, the pressure in the chamber is set to, e.g., about 4.0 to 13.3 Pa (about 0.03 to 0.1 Torr). When the temperature of the wafer W reaches the relatively low second temperature, e.g., about 130 to 150° C., the stabilization is carried out by supplying a carrier gas and a dilution gas as in the first embodiment. Next, in a state where the carrier gas and the dilution gas are supplied, liquid Cu(hfac)TMVS is vaporized by the vaporizer at about 50 to 70° C. and introduced into the chamber, thereby depositing Cu (step 38). At this time, Cu(hfac)TMVS is supplied at a flow rate of, e.g., about 100 to 500 mg/min, which is smaller than the flow rate during the nucleus formation. Hence, as in the first embodiment, Cu is deposited to cover the initial nucleus of Cu 202 by the reaction of Eq. (1), and the Cu film 203 is formed, as can be seen from FIG. 4.

After the Cu deposition unit 112 is purged, the wafer W is transferred to the transfer chamber 65 by the transfer device 72, and then is transferred to any one of the carriers C by the transfer device 76 via the load-lock chambers 66 and 67 (step 39).

As described above, in the present embodiment, nuclei of Cu are formed at the relatively high first temperature (higher than the second temperature as a film forming temperature), so that it is possible to shorten a period of time required to form nuclei, especially an incubation time. Thereafter, Cu is deposited at the relatively low second temperature (lower than the first temperature), so that a Cu film having high smoothness and good surface properties can be formed while suppressing agglomeration of Cu. In other words, a CVD-Cu film having good surface properties can be formed at a high film forming speed.

After the wafer W is heated to a temperature higher than the initial nucleus formation temperature by the preliminary heating unit 91, the initial nucleus formation and the Cu deposition are carried out without heating the wafer W in the Cu initial nucleus formation unit 111 and the Cu film formation unit 112 which are provided separately. As a result, residual heat is not transferred to the wafer W, and the agglomeration of Cu can be effectively prevented.

Since the wafer W is transferred to the Cu deposition unit 112 after completion of the initial nucleus formation in the Cu initial nucleus formation unit 111, the wafer W can be cooled while being transferred. Further, the waiting time for changing conditions or the like can be decreased even though the wafer transfer time is required.

### TEST EXAMPLE

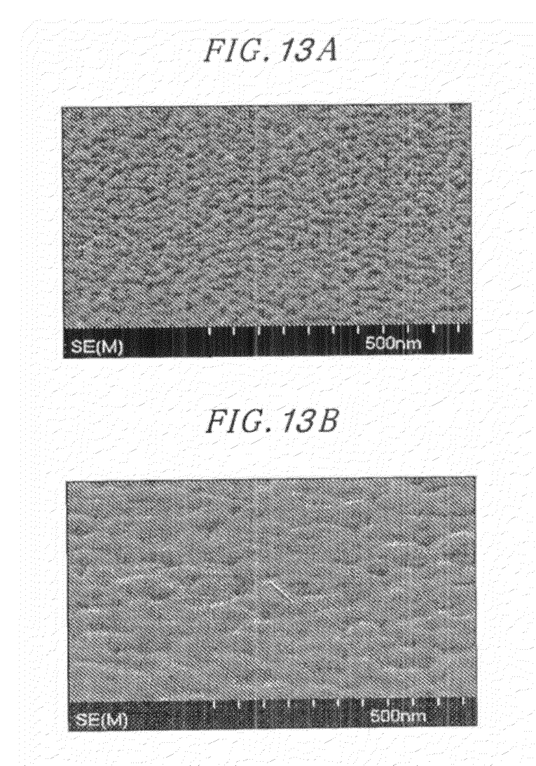

Here, a Cu film having a thickness of about 30 nm was formed by the method of the third embodiment while using Cu(hfac)TMVS as a film-forming source material. A wafer was preliminarily heated to about 350° C. and, then, initial nuclei were formed. Thereafter, Cu was deposited at about 150° C. Accordingly, more than five minutes was reduced compared to the case of forming a Cu film by performing the initial nucleus formation and the Cu deposition at a conventional temperature of about 150° C. This is mainly because the incubation time is reduced. The state obtained after the initial nucleus formation and the state obtained after the Cu deposition are shown in the scanning electron microscope (SEM) images of FIGS. 13A and 13B. As clearly seen from those images, the high-density initial nuclei and the film having high smoothness were obtained in this case.

### <Another Application of the Present Invention>

The present invention can be variously modified without being limited to the above embodiment. For example, although the case in which Cu(hfac)TMVS is used as a Cu complex has been described in the above embodiment, it is not limited thereto.

In the above embodiment, a Cu complex in a liquid state is force-fed to a vaporizer and then is vaporized therein. However, it may be vaporized in a different manner, e.g., bubbling or the like, other than the above-described manner.

Further, the film forming apparatus is not limited to that of the above embodiment, and there can be used various apparatuses such as an apparatus including a mechanism for forming a plasma to facilitate decomposition of a film-forming material gas and the like.

Although the case in which a semiconductor wafer is used as a substrate to be processed has been described, another substrate such as a flat panel display (FPD) substrate or the like may also be used without being limited thereto.

What is claimed is:

1. A method for forming a Cu film on a substrate by a CVD method, comprising:
forming initial nuclei of Cu on a substrate by supplying a film-forming source material including a Cu complex to the substrate kept at a relatively high first temperature; and
depositing Cu on the substrate having the initial nuclei of Cu formed thereon by supplying a film-forming source material including a Cu complex to the substrate kept at a relatively low second temperature.

2. The method of claim 1, wherein the Cu complex is a monovalent Cu complex.

3. The method of claim 1, wherein the substrate has a Ru film formed thereon by CVD, and the initial nuclei of Cu are formed on the Ru film.

4. The method of claim 1, wherein the first temperature is about 240 to 280° C., and the second temperature is about 150 to 130° C.

5. The method of claim 1, further comprising, after forming the initial nuclei of Cu, cooling the substrate.

6. The method of claim 1, wherein after the substrate mounted on a susceptor is heated to a temperature close to the first temperature in a processing chamber by heating the susceptor by a heater while setting the pressure in the processing chamber to a relatively high first pressure, the formation of the initial nuclei of Cu is performed while setting the pressure in the processing chamber to a relatively low second pressure and heating the substrate to the first temperature, and the deposition of Cu is performed when the substrate temperature reaches the second temperature.

7. The method of claim 1, wherein after the initial nuclei of Cu are formed in a first unit, and the deposition of Cu is performed in a second unit.

8. The method of claim 1, further comprising, before forming the initial nuclei of Cu, preliminarily heating the substrate to a temperature higher than the first temperature, wherein the formation of the initial nuclei of Cu and the deposition of Cu are performed without heating the preliminarily heated substrate.

9. The method of claim 8, wherein the preliminary heating temperature is higher than the first temperature.

10. The method of claim 8, wherein the preliminary heating is performed in a preliminary heating unit, and the formation of the initial nuclei of Cu and the deposition of Cu are performed in a Cu film formation unit.

11. The method of claim 8, wherein the preliminary heating is performed in a preliminary heating unit; the formation of the initial nuclei of Cu is performed in a Cu initial nucleus formation unit; and the deposition of Cu is performed in a Cu deposition unit.

12. A computer readable storage medium storing a program for controlling a film forming apparatus,
wherein the program, when executed, controls the film forming apparatus in a computer such that a method for forming a Cu film is performed, the method for forming a Cu film including:
forming initial nuclei of Cu on a substrate by supplying a film-forming source material including a Cu complex to the substrate kept at a relatively high first temperature; and
depositing Cu on the substrate having the initial nuclei of Cu formed thereon by supplying a film-forming source material including a Cu complex to the substrate kept at a relatively low second temperature.
